(19) United States
(12) Patent Application Publication
(10) Pub. No.: US 2013/0114628 A1
(43) Pub. Date: May 9, 2013

(54) MULTI-WAVELENGTH DBR LASER

(71) Applicants: Catherine Genevieve Caneau, Corning, NY (US); Feng Xie, Painted Post, NY (US); Chung-En Zah, Holmdel, NJ (US)

(72) Inventors: Catherine Genevieve Caneau, Corning, NY (US); Feng Xie, Painted Post, NY (US); Chung-En Zah, Holmdel, NJ (US)

(21) Appl. No.: 13/570,719

(22) Filed: Aug. 9, 2012

Related U.S. Application Data
(60) Provisional application No. 61/556,434, filed on Nov. 7, 2011.

(51) Int. Cl. H01S 5/125

(52) U.S. Cl. 372/20

(57) ABSTRACT

A multi-wavelength distributed Bragg reflector (DBR) laser diode is provided including front and rear DBR sections and a plurality of dedicated tuning signal control nodes. The front DBR section includes a plurality of front wavelength selective grating sections defining a plurality of distinct grating periodicities λ₁*, λ₂* . . . corresponding to distinct Bragg wavelengths λ_{S1}*, λ_{S2}* . . . . The rear DBR section comprises a plurality of rear wavelength selective grating sections defining a plurality of distinct grating periodicities λ₁, λ₂ . . . corresponding to distinct Bragg wavelengths λ_{S1}, λ_{S2} . . . . The tuning signal control nodes are associated with corresponding front wavelength selective grating sections, rear wavelength selective grating sections, or both, such that tuning signals applied to one or more of the dedicated tuning signal control nodes spectrally aligns select Bragg wavelengths λ_{S1}*, λ_{S2}* . . . of the front DBR section with a selected distinct Bragg wavelengths λ_{S1}, λ_{S2} . . . of the rear DBR section.

### CROSS-REFERENCE TO RELATED APPLICATIONS

This application claims the benefit of priority under 35 U.S.C. §119 of U.S. Provisional Application Ser. No. 61/556,434 filed on Nov. 7, 2011.

### BACKGROUND

The present disclosure relates to laser diodes characterized by multi-wavelength emission and, more particularly, to distributed Bragg reflector (DBR) quantum cascade (QCL) laser diodes. The present disclosure also relates to the use of such lasers as a mid-IR tunable source in the identification of molecular compositions in, for example, gas sensing and medical diagnostics, although the concepts of the present disclosure will enjoy broad applicability in a variety of fields.

### BRIEF SUMMARY

The present disclosure is directed to multi-wavelength DBR QCL products that can be operated to generate several wavelengths sequentially in time. The resulting emission can be used, for example, to sample a broad absorption line. Particular embodiments of the present disclosure are limited to uni-polar QCLs, which use inter-sub-band transitions to produce photons, but it is also contemplated that the concepts of the present disclosure can be adapted for use with bi-polar lasers, which use inter-band transitions to produce photons.

In accordance with one embodiment of the present disclosure, a multi-wavelength distributed Bragg reflector (DBR) laser diode is provided comprising front and rear DBR sections and a plurality of dedicated tuning signal control nodes. The front DBR section comprises a plurality of front wavelength selective grating sections defining a plurality of distinct grating periodicities Λ₁*, Λ₂* . . . corresponding to distinct Bragg wavelengths λ_{S1}*, λ_{S2}* . . . . The rear DBR section comprises a plurality of rear wavelength selective grating sections defining a plurality of distinct grating periodicities Λ₁, Λ₂ . . . corresponding to distinct Bragg wavelengths λ_{S1}, λ_{S2} . . . . The plurality of dedicated tuning signal control nodes are associated with individual ones of the front wavelength selective grating sections, individual ones of the rear wavelength selective grating sections, or both, and are constructed such that one or more tuning signals applied to one or more of the dedicated tuning signal control nodes spectrally aligns distinct Bragg wavelengths a selected one of the distinct Bragg wavelengths λ_{S1}*, λ_{S2}* . . . of the front DBR section with a selected one of the distinct Bragg wavelengths λ_{S1}, λ_{S2} . . . of the rear DBR section.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 is a schematic illustration of a multi-wavelength distributed Bragg reflector (DBR) quantum cascade laser diode according to the present disclosure;

FIG. 2 illustrates the characteristics of the front and rear grating portions of an un-tuned multi-wavelength DBR according to the present disclosure;

FIG. 3 illustrates a method of tuning a multi-wavelength DBR according to one embodiment of the present disclosure; and

FIG. 4 illustrates a method of tuning a multi-wavelength DBR according to an alternative embodiment of the present disclosure.

### DETAILED DESCRIPTION

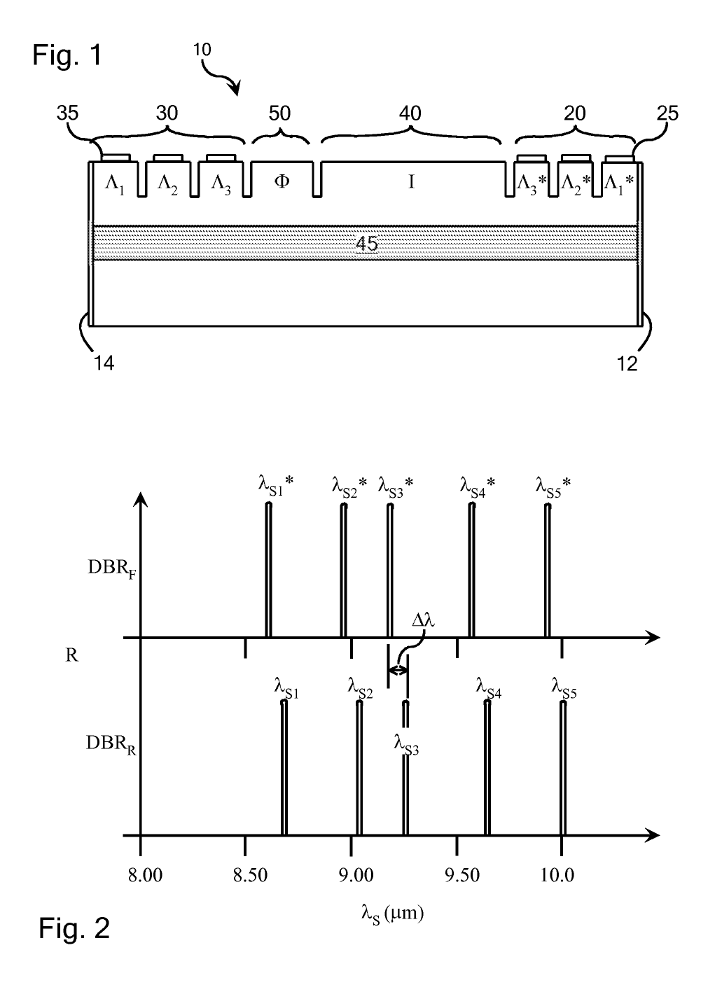

The general structure of a multi-wavelength DBR laser diode 10 according to the present invention is illustrated in FIG. 1. In FIG. 1, the DBR 10 comprises front and rear DBR sections 20, 30, a plurality of dedicated tuning signal control nodes 25, 35, a gain section 40, a phase section 50, and a waveguide core 45 extending between the front and rear facets 12, 14 of the laser diode 10. The gain section 40 may comprise a quantum cascade active region and is positioned between the front and rear DBR sections 20, 30 along an optical propagation axis defined by the waveguide core 45 of the laser diode 10.

As will be appreciated by those familiar with DBR lasers, a DBR section of a DBR laser comprises Bragg gratings, i.e., a light-reflecting device based on Bragg reflection by a periodic structure. The periodic structure of the DBR section defines the Bragg wavelength λ_{B} of the laser. The front and rear DBR sections 20, 30 of the present disclosure do not rely upon periodic or aperiodic shifts in the grating phase Φ or chirped grating periodicities to generate multiple wavelength selection capabilities. Further, the respective reflectivity peaks of the front and rear DBR sections 20, 30 are spaced such that they do not overlap each other, although individual reflectivity peaks of the front DBR section 20 can be tuned to match a selected reflectivity peak of the rear DBR section 30, as will be explained in detail below.

The present disclosure is directed to the particulars of the front and rear DBR sections 20, 30. The respective structures of the waveguide core 45, the associated waveguide layers, the gain and phase sections 40, 50, and the anti-reflection coatings can be gleaned from readily available teachings in the art. As is illustrated in FIGS. 1 and 2, the front DBR section 20 comprises a plurality of front wavelength selective grating sections defining a plurality of distinct grating periodicities Λ₁*, Λ₂* . . . corresponding to distinct Bragg wavelengths λ_{S1}*, λ_{S2}* . . . distinct Bragg wavelengths Similarly, the rear DBR section 30 comprises a plurality of rear wavelength selective grating sections defining a plurality of distinct grating periodicities Λ₁, Λ₂ . . . corresponding to distinct Bragg wavelengths λ_{S1}, λ_{S2} . . . distinct Bragg wavelengths

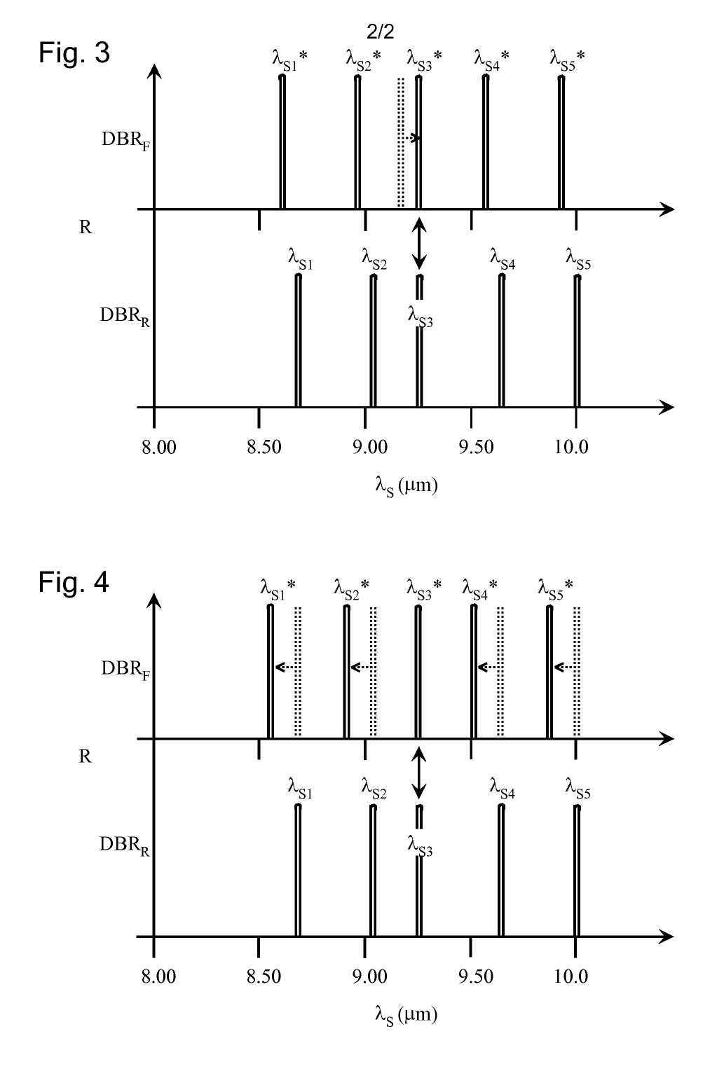

As is illustrated schematically in FIG. 2, in one embodiment of the present disclosure, each of the distinct Bragg wavelengths λ_{S1}*, λ_{S2}* . . . is spectrally misaligned with respect to the distinct Bragg wavelengths λ_{S1}, λ_{S2} . . . However, the wavelength selective grating sections comprise dedicated tuning signal control nodes 25, 35 that are associated with individual ones of the front wavelength selective grating sections, individual ones of the rear wavelength selective grating sections, or both. In operation, as is illustrated in FIG. 3, a tuning signal is applied to one of the dedicated tuning signal control nodes 25, 35 to alter a selected one of the distinct Bragg wavelengths, i.e., λ_{S3}*, and place it into spectral alignment with a selected one of the distinct Bragg wavelengths, i.e., λ_{S3}, to generate emission at the selected emission wavelength—λ_{S3} in the illustrated example. Successive tuning signals can be tailored for emission at successive emission wavelengths λ_{S1}, λ_{S2} . . .

Although, in the embodiment illustrated in FIGS. 2 and 3, each of the distinct Bragg wavelengths λ_{S1}*, λ_{S2}* . . . are shorter than the corresponding distinct Bragg wavelengths λ_{S1}, λ_{S2} . . . it is noted that a variety of “un-tuned” states are contemplated according to the present disclosure. For example, the distinct Bragg wavelengths λ_{S1}*, λ_{S2}* . . . could be shorter and/or longer than the corresponding distinct Bragg wavelengths λ_{S1}, λ_{S2} . . . Typically, long wavelength grating sections will be aligned with the a corresponding shorter Bragg wavelength grating sections in the opposite DBR section of the laser diode by activating the tuning signal control nodes, e.g., micro-heaters or direct current injection electrodes, in the short wavelength grating section, although a variety of control node configurations are contemplated.

As a further example, it is contemplated that one or more of the distinct Bragg wavelengths λ_{S1}*, λ_{S2}* . . . could be spectrally aligned with respect to the distinct Bragg wavelengths λ_{S1}, λ_{S2} . . . in the “un-tuned” state. In which case, in a “tuned” state, one or more tuning signals could be applied to the dedicated front tuning signal control nodes 25 or rear tuning signal control nodes 30 to alter selected ones of the distinct Bragg wavelengths λ_{S1}*, λ_{S2}* . . . such that all but one of the distinct Bragg wavelengths λ_{S1}*, λ_{S2}* . . . are spectrally misaligned with respect to the distinct Bragg wavelengths λ_{S1}, λ_{S2} . . . This configuration and procedure is illustrated in FIG. 4. In practice, it may be beneficial to ensure that each of the distinct Bragg wavelengths λ_{S1}*, λ_{S2}* . . . are spectrally misaligned with respect to the distinct Bragg wavelengths λ_{S1}, λ_{S2} . . . by approximately 4.1 cm⁻¹ or more (wave number) for a DBR length of 0.5 mm. The spectral separation should be increased with reduced DBR length.

As is further illustrated in FIG. 1, the rear wavelength selective grating sections of the rear DBR section 30 may also be provided with a control mechanism. This control mechanism may take the form of a laser diode heat sink or the illustrated rear tuning signal control nodes 35, which can be associated with individual ones of the rear wavelength selective grating sections of the rear DBR section 30. Where the laser diode is provided with a heat sink or some other temperature control mechanism that is common to both the front and rear DBR sections 20, 30, it is contemplated that thermal control of the front and rear DBR sections 20, 30 can be executed by either tuning the heat sink temperature, tuning the tuning signal control nodes 25, 35, or both.

In cases where the front and rear tuning signal control nodes 25, 35 comprise thermal tuning nodes, e.g., micro-heater elements, it will typically be advantageous to ensure that each of the distinct Bragg wavelengths λ_{S1}*, λ_{S2}* . . . are shorter than the distinct Bragg wavelengths λ_{S1}, λ_{S2} . . . so that a temperature increase initiated by one of the front thermal tuning nodes will increase the corresponding tuning wavelength to bring it into alignment with the target emission wavelength. It is also contemplated that the front and rear tuning signal control nodes 25, 35 may comprise electrical contacts for direct current injection to the front and rear wavelength selective grating sections. Finally, it is contemplated that individual ones of the tuning signal control nodes 25, 35 could be operated together, as a single control node, depending upon the operational demands of the particular application.

In cases where the gain section 40 of the laser diode 10 is characterized by a wavelength-dependent optical gain spectrum it will typically be preferable to arrange the front and rear wavelength selective grating sections of the front and rear DBR sections 20, 30 such that grating sections corresponding to reflectance peaks in relatively low gain portions of the optical gain spectrum are positioned relatively close to the gain section 40 of the laser diode 10, while grating sections corresponding to reflectance peaks in relatively high gain portions of the optical gain spectrum are positioned relatively far from the gain section 40 of the laser diode 10.

The waveguide core 45 of the laser diode 10 may comprise a stack of quantum cascade cores and each quantum cascade core may be configured to define a gain peak approximating one of the distinct Bragg wavelengths λ_{S1}, λ_{S2} . . . of the rear wavelength selective grating sections. Alternatively, the waveguide core 45 of the laser diode 10 may comprise a single quantum cascade core with a gain spectrum that is broad enough to encompass the distinct Bragg wavelengths λ_{S1}, λ_{S2} . . . of the rear wavelength selective grating sections. In many cases, the gain section 40 of the laser diode 10 will be characterized by a wavelength-dependent optical gain spectrum. To account for this, it is contemplated that quantum cascade cores with relatively low optical gains can be placed relatively close to the center of the optical mode of propagation of the laser diode 10, while quantum cascade cores with relatively high optical gains can be placed relatively far from the center of the optical mode of propagation of the laser diode 10. Alternatively, or additionally, cores with relatively low optical gain can be constructed with a greater number of stages or higher confinement factors, and cores with relatively high optical gain can be constructed with a fewer number of stages or lower confinement factors. As a further alternative, it is contemplated that shorter wavelength cores can be placed near the center of the waveguide core 45, with longer wavelength cores outside, because optical mode size at longer wavelengths is larger than at relatively short wavelengths.

Preferably, the waveguide core 45 of the laser diode 10 comprises a uni-polar QCL using inter-sub-band transitions to produce photons. However, it is also contemplated that the waveguide core 45 of the laser diode 10 may comprise a bi-polar laser using inter-band transitions to produce photons.

For example, and not by way of limitation, in one implementation of the concepts of the present disclosure, the distinct Bragg wavelengths λ_{S1}, λ_{S2} . . . are selected to be the sampling wavelengths of a relatively broad absorption line, i.e., approximately 150 cm⁻¹ spectral width. To this end, FIGS. 2 and 3 show five reflection peaks that can be generated using five 0.75 mm long rear wavelength selective grating sections selected to match the five absorption peaks of glucose. Noting that the power needed to thermally tune the wavelength is less for shorter DBR sections than longer DBR sections, generally, the front wavelength selective grating sections are shorter than the rear sections to allow higher output power. In a more specific implementation, the spectral distance between the Bragg wavelength of a selected grating section and the 1^{st} null of the DBR is about 4.1 cm⁻¹ (ΔβL=2πn_{g}ΔwL), assuming a grating length of 0.5 mm. For sampling wavelengths to be outside the grating bandwidth of sampling wavelengths in the rear DBR sections, the front reflectivity peaks should be set at approximately 4.1 cm⁻¹ shorter than one of the rear sampling wavelengths such that each can be tuned to match the nearby sampling wavelength by heating using a micro-heater or direct current injection. Thermal tuning efficiencies determined from a 4.57 μm DBR QCL are approximately 11 cm⁻¹W⁻¹mm and 15 cm⁻¹W⁻¹mm, using a microheater or current injection, respectively. The heating power required to align the Bragg wavelength of a 0.5 mm long front grating to one of the sampling wavelengths is estimated to be 186 mW and 137 mW using a micro-heater or current injection, respectively.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “substantially” and “approximately” are utilized herein to represent the inherent degree of uncertainty that may be attributed to any quantitative comparison, value, measurement, or other representation. The terms “substantially” and “approximately” are also utilized herein to represent the degree by which a quantitative representation may vary from a stated reference without resulting in a change in the basic function of the subject matter at issue.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

What is claimed is:

1. A multi-wavelength distributed Bragg reflector (DBR) laser diode comprising front and rear DBR sections, a plurality of dedicated tuning signal control nodes, a gain section, and a waveguide core extending between front and rear facets of the laser diode, wherein:
the gain section comprises an active region and is positioned between the front and rear DBR sections along an optical propagation axis defined by the waveguide core of the laser diode;
the front DBR section comprises a plurality of front wavelength selective grating sections defining a plurality of distinct grating periodicities Λ₁*, Λ₂* . . . corresponding to distinct Bragg wavelengths λ_{S1}*, λ_{S2}* . . . ;
the rear DBR section comprises a plurality of rear wavelength selective grating sections defining a plurality of distinct grating periodicities Λ₁, Λ₂ . . . corresponding to distinct Bragg wavelengths λ_{S1}, λ_{S2} . . . ;
the plurality of dedicated tuning signal control nodes are associated with individual ones of the front wavelength selective grating sections, individual ones of the rear wavelength selective grating sections, or both, and are constructed such that one or more tuning signals applied to one or more of the dedicated tuning signal control nodes spectrally aligns distinct Bragg wavelengths a selected one of the distinct Bragg wavelengths λ_{S1}*, λ_{S2}* . . . of the front DBR section with a selected one of the distinct Bragg wavelengths λ_{S1}, λ_{S2} . . . of the rear DBR section.

2. A laser diode as claimed in claim 1 wherein:
the front or rear wavelength selective grating sections and the dedicated front or rear tuning signal control nodes are constructed such that a tuning signal applied to one of the dedicated front or rear tuning signal control nodes will place a selected one of the distinct Bragg wavelengths λ_{S1}*, λ_{S2}* . . . into spectral alignment with a selected one of the distinct Bragg wavelengths λ_{S1}, λ_{S2}; and
the distinct Bragg wavelengths λ_{S1}*, λ_{S2}* . . . are shorter or longer than the distinct Bragg wavelengths λ_{S1}, λ_{S2}.

3. A laser diode as claimed in claim 2 wherein the front and rear wavelength selective grating sections and the dedicated front and rear tuning signal control nodes are constructed such that a tuning signal applied to a dedicated front or rear tuning signal control node associated with a shorter wavelength places a selected one of the distinct Bragg wavelengths λ_{S1}*, λ_{S2}* . . . into spectral alignment with a selected one of the distinct Bragg wavelengths λ_{S1}, λ_{S2}.

4. A laser diode as claimed in claim 2 wherein each of the distinct Bragg wavelengths λ_{S1}*, λ_{S2}* . . . are spectrally misaligned with respect to the corresponding distinct Bragg wavelengths λ_{S1}, λ_{S2} . . . by approximately 4.1 cm⁻¹ or more for a DBR length of 0.5 mm.

5. A laser diode as claimed in claim 1 wherein:
one or more of the distinct Bragg wavelengths λ_{S1}*, λ_{S2}* . . . are spectrally aligned with respect to the distinct Bragg wavelengths λ_{S1}, λ_{S2} . . . ; and
the front wavelength selective grating sections and the dedicated front tuning signal control nodes are constructed such that tuning signals applied to the dedicated front tuning signal control nodes will alter selected ones of the distinct Bragg wavelengths λ_{S1}*, λ_{S2}* . . . such that all but one of the distinct Bragg wavelengths λ_{S1}*, λ_{S2}* . . . are spectrally misaligned with respect to the distinct Bragg wavelengths λ_{S1}, λ_{S2}.

6. A laser diode as claimed in claim 1 wherein:
the front tuning signal control nodes comprise thermal tuning nodes; and
each of the distinct Bragg wavelengths λ_{S1}*, λ_{S2}* . . . are shorter than the distinct Bragg wavelengths λ_{S1}, λ_{S2} . . . such that a temperature increase initiated by one or more of the front thermal tuning nodes will increase the distinct Bragg wavelengths λ_{S1}*, λ_{S2}* . . .

7. A laser diode as claimed in claim 1 wherein the front tuning signal control nodes comprise electrical contacts for direct current injection to the front wavelength selective grating sections.

8. A laser diode as claimed in claim 1 wherein:
the rear wavelength selective grating sections comprise one or more rear tuning signal control nodes associated with the rear wavelength selective grating sections; and
the rear tuning signal control nodes are constructed such that one or more tuning signals applied to one or more of the rear tuning signal control nodes will alter one or more of the distinct Bragg wavelengths λ_{S1}, λ_{S2} . . .

9. A laser diode as claimed in claim 1 wherein a dedicated front control node comprises a single control node associated with a single front wavelength selective grating section or a plurality of tuning signal control nodes associated with a single front wavelength selective grating section.

10. A laser diode as claimed in claim 1 wherein:
the waveguide core of the laser diode comprises a stack of quantum cascade cores; and
each quantum cascade core comprises a gain peak approximating one of the distinct Bragg wavelengths λ_{S1}, λ_{S2} . . . of the rear wavelength selective grating sections.

11. A laser diode as claimed in claim 10 wherein:
the gain section of the laser diode is characterized by a wavelength-dependent optical gain spectrum; and
the quantum cascade cores with relatively low optical gains are placed relatively close to the center of the optical mode of propagation of the laser diode, while the quantum cascade cores with relatively high optical gains are placed relatively far from the center of the optical mode of propagation of the laser diode.

12. A laser diode as claimed in claim 10 wherein:
the gain section of the laser diode is characterized by a wavelength-dependent optical gain spectrum; and
the quantum cascade cores with relatively low optical gains are constructed with a relatively high number of stages or relatively high confinement factors, while the quantum cascade cores with relatively high optical gains are constructed with a relatively low number of stages or relatively low confinement factors.

13. A laser diode as claimed in claim 10 wherein:
relatively short wavelength quantum cascade cores are placed relatively close to the center of the optical mode of propagation of the laser diode, while relatively long wavelength quantum cascade cores are placed relatively far from the center of the optical mode of propagation of the laser diode.

14. A laser diode as claimed in claim 1 wherein the waveguide core of the laser diode comprises a single quantum cascade core with a gain spectrum that is broad enough to encompass the distinct Bragg wavelengths λ_{S1}, λ_{S2} . . . of the rear wavelength selective grating sections.

15. A laser diode as claimed in claim 1 wherein the waveguide core of the laser diode comprises a uni-polar QCL using inter-sub-band transitions to produce photons.

16. A laser diode as claimed in claim 1 wherein the waveguide core of the laser diode comprises a bi-polar laser using inter-band transitions to produce photons.

17. A laser diode as claimed in claim 1 wherein:
the gain section of the laser diode is characterized by a wavelength-dependent optical gain spectrum; and
the front and rear wavelength selective grating sections are arranged along the optical propagation axis of the laser diode such that grating sections corresponding to reflectance peaks in relatively low gain portions of the optical gain spectrum are positioned relatively close to the gain section of the laser diode, while grating sections corresponding to reflectance peaks in relatively high gain portions of the optical gain spectrum are positioned relatively far from the gain section of the laser diode.

18. A laser diode as claimed in claim 1 wherein:
the gain section of the laser diode is characterized by a wavelength-dependent optical gain spectrum; and
the front grating section corresponding to a reflectance peak in the lowest gain portion of the optical gain spectrum is positioned closest to the gain section along a front portion of the optical propagation axis of the laser diode.

19. A laser diode as claimed in claim 1 wherein:
the gain section of the laser diode is characterized by a wavelength-dependent optical gain spectrum; and
the rear grating section corresponding to a reflectance peak in the lowest gain portion of the optical gain spectrum is positioned closest to the gain section along a rear portion of the optical propagation axis of the laser diode.

20. A multi-wavelength distributed Bragg reflector (DBR) laser diode comprising front and rear DBR sections, a plurality of dedicated tuning signal control nodes, a gain section, and a waveguide core extending between front and rear facets of the laser diode, wherein:
the gain section comprises an active region and is positioned between the front and rear DBR sections along an optical propagation axis defined by the waveguide core of the laser diode;
the front DBR section comprises a plurality of front wavelength selective grating sections defining a plurality of distinct grating periodicities Λ₁*, Λ₂* . . . corresponding to distinct Bragg wavelengths λ_{S1}*, λ_{S2}* . . . ;
the rear DBR section comprises a plurality of rear wavelength selective grating sections defining a plurality of distinct grating periodicities Λ₁, Λ₂ . . . corresponding to distinct Bragg wavelengths λ_{S1}, λ_{S2} . . . ;
each of the distinct Bragg wavelengths λ_{S1}*, λ_{S2}* . . . are shorter than and spectrally misaligned with respect to the distinct Bragg wavelengths λ_{S1}, λ_{S2} . . . ;
the plurality of dedicated tuning signal control nodes are associated with individual ones of the front wavelength selective grating sections and are constructed such that one or more tuning signals applied to one or more of the front dedicated tuning signal control nodes spectrally aligns distinct Bragg wavelengths a selected one of the distinct Bragg wavelengths λ_{S1}*, λ_{S2}* . . . of the front DBR section with a selected one of the distinct Bragg wavelengths λ_{S1}, λ_{S2} . . . of the rear DBR section;
the waveguide core of the laser diode comprises a stack of quantum cascade cores;
each quantum cascade core comprises a gain peak approximating one of the distinct Bragg wavelengths λ_{S1}, λ_{S2} . . . of the rear wavelength selective grating sections;
the gain section of the laser diode is characterized by a wavelength-dependent optical gain spectrum;
the quantum cascade cores with relatively low optical gains are placed relatively close to the center of the optical mode of propagation of the laser diode, while the quantum cascade cores with relatively high optical gains are placed relatively far from the center of the optical mode of propagation of the laser diode; and
the front grating section corresponding to a reflectance peak in the lowest gain portion of the optical gain spectrum is positioned closest to the gain section along a front portion of the optical propagation axis of the laser diode.
